(19) United States
(12) Patent Application Publication
(10) Pub. No.: US 2026/0245594 A1
(43) Pub. Date: Aug. 20, 2026

(54) Memory Circuitry And Methods Used In Forming Memory Circuitry

(71) Applicant: Micron Technology, Inc., Boise, ID (US)

(72) Inventors: David K. Hwang, Boise, ID (US); Ruijing Ge, Boise, ID (US); Si-Woo Lee, Saratoga, CA (US)

(73) Assignee: Micron Technology, Inc., Boise, ID (US)

(21) Appl. No.: 19/055,923

(22) Filed: Feb. 18, 2025

Related U.S. Application Data
(60) Provisional application No. 63/747,142, filed on Jan. 20, 2025.

(51) Int. Cl. G11C 5/06; H10B 12/00

(52) U.S. Cl. CPC G11C 5/063; H10B 12/05; H10B 12/09; H10B 12/488; H10B 12/50

(57) ABSTRACT

Memory circuitry comprises vertically alternating insulative tiers and memory-cell tiers. Memory cells are in the memory-cell tiers and individually comprise a horizontal transistor comprising a top gate and a bottom gate having channel material vertically there-between. The top and bottom gates comprise part of one of a plurality of access lines that individually directly electrically couple together multiple of the gates of different ones of the horizontal transistors that are in the same memory-cell tier. Top and bottom surfaces of the individual access lines are everywhere horizontally planar between immediately-x-direction-adjacent horizontal transistors. Other embodiments, including method, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a vertical z direction) comprising a three-dimensional (3D) memory array region having horizontal tiers in which individual memory cells are received (e.g., arrayed in horizontal x and y directions). The stack in the 3D memory array region comprises vertically-alternating insulative tiers and conductive tiers (e.g., as part of memory-cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-9 are diagrammatic sectional views of constructions in accordance with embodiments of the invention.

FIGS. 10-22 are diagrammatic sequential sectional and/or enlarged views of the construction of FIGS. 3-8, or portions thereof or alternate and/or additional embodiments, in process in accordance with some embodiments of the invention.

### DETAILED DESCRIPTION OF EXAMPLE EMBODIMENTS

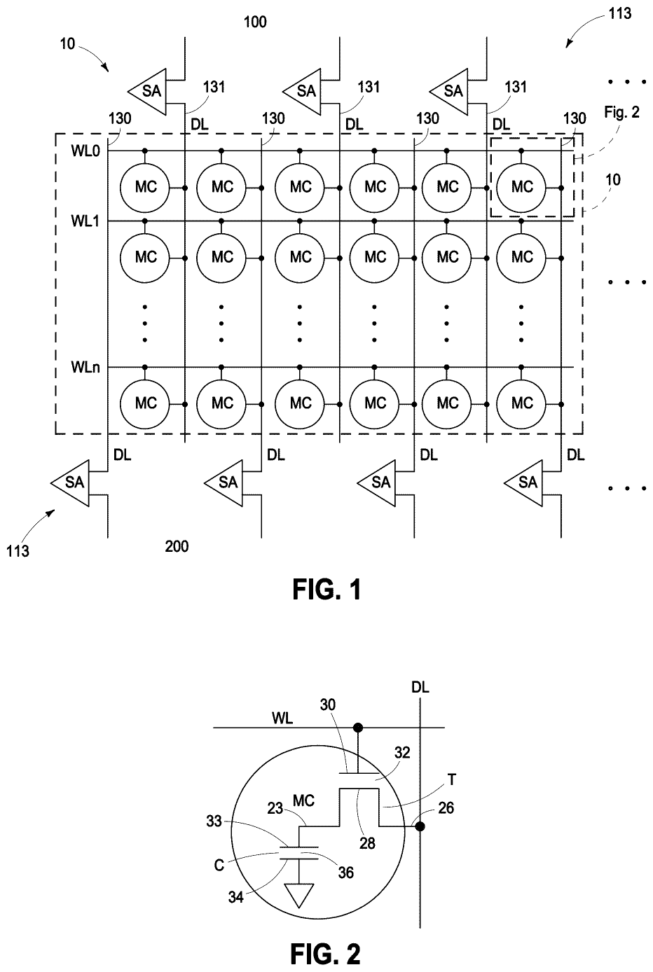

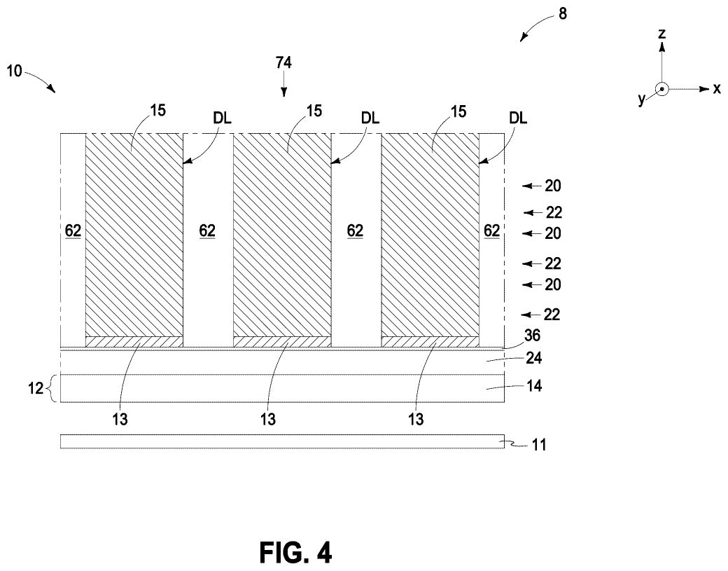

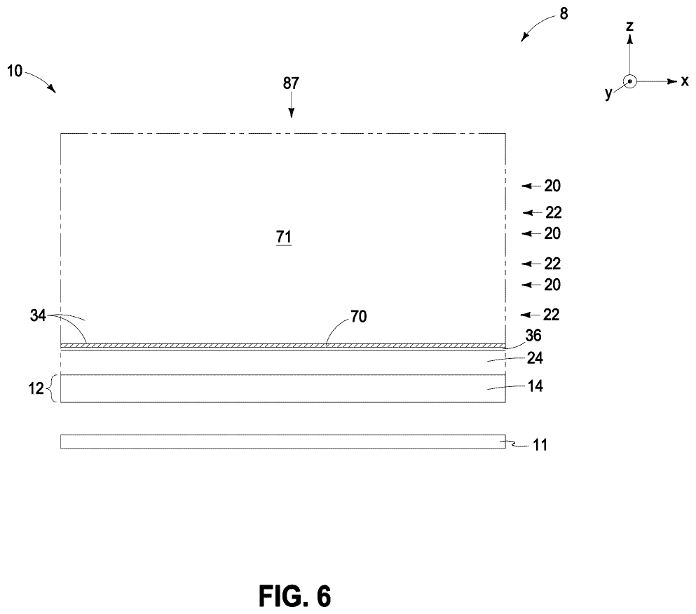

Embodiments of the invention encompass memory circuitry (e.g., DRAM) comprising vertically-stacked memory cells individually comprising a horizontal transistor and, in some embodiments, a capacitor electrically coupled therewith. Embodiments of the invention also encompass methods used in forming such memory circuitry. Example structure embodiments are first described with reference to FIGS. 1-8.

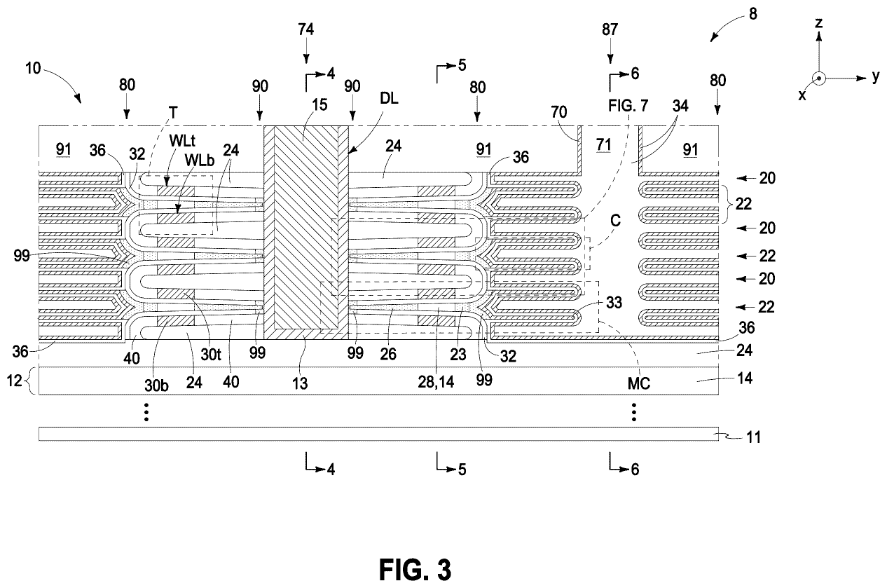

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part thereof) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIGS. 3+ have the wordlines/access lines running horizontally and the digitlines/sense lines running vertically.

Referring to FIGS. 3-8, an example fragment of a substrate construction 8 comprising array or array area 10 has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3-8-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array. Example construction 8 comprises a semiconductor substrate 12 (e.g., monocrystalline silicon 14) having insulative material 24 there-above (e.g., silicon dioxide and/or silicon nitride).

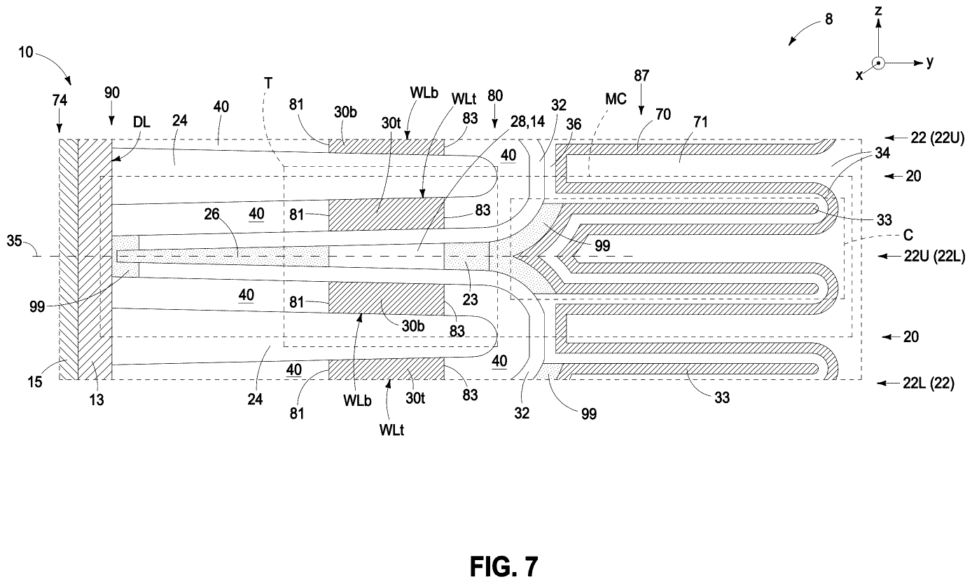

Example memory circuitry (e.g., that of or comprising construction 8) comprises vertically-alternating insulative tiers 20 and memory-cell tiers 22* (e.g., along example direction z; an * being used as a suffix to be inclusive of all such same-numerically-designated structures or portions thereof that may or may not have other suffixes). Insulative tiers 20 comprise insulative material 24 that is vertically between immediately-vertically-adjacent memory-cell tiers 22*. An example insulating material/hardmask 91 (e.g., silicon dioxide) is above tiers 20 and 22*. Memory cells MC are in memory-cell tiers 22* and individually comprise a horizontal transistor T and, in some embodiments, a capacitor C. Horizontal transistor T has a gate 30*, a capacitor side 80, and a digitline side 90. A horizontally-elongated trench 74 is shown in construction 8 on digitline side 90 (e.g., a digitline trench). A horizontally-elongated trench 87 is shown in construction 8 on capacitor side 80 (e.g., a capacitor trench). Capacitor C is electrically coupled (e.g., directly electrically coupled) with horizontal transistor T on capacitor side 80. A digitline DL is electrically coupled (e.g., directly electrically coupled) with horizontal transistor T on digitline side 90. Immediately-vertically-adjacent of the memory-cell tiers comprise an upper memory-cell tier (e.g., 22U in FIG. 7) and a lower memory-cell tier (e.g., 22L in FIG. 7) (there being no other such noun [tier] between those that are immediately-adjacent one another). Each memory-cell tier 22* may of course be considered as either an upper or a lower memory-cell tier depending on whether “immediately-vertically-adjacent” is referring to above or below with respect to the tiers 22* at issue.

Example horizontal transistor T comprises a first source/drain region 23 (e.g., conductively-doped silicon), a second source/drain region 26 (e.g., conductively-doped silicon), and a channel region 28 (e.g., lightly-doped or undoped silicon 14) horizontally between the first and second source/drain regions. The y-direction lengths of regions 23, 26, and 28 are diagrammatic in the figures. Such may be of equal or different lengths relative one another than is shown. Regions 23 and 26 of different immediately-horizontally-adjacent memory cells MC running into and out of the plane of the page upon which FIG. 3 lies in a common memory-cell tier 22* (along a horizontal x-direction) may be isolated relative one another by insulative material (not shown). A horizontal axis 35 (FIG. 7) extends from capacitor side 80 to digitline side 90 through channel region 28 and source/drain regions 23, 26 along a horizontal y-direction (that is perpendicular the x-direction). Regions 23, 26, and/or 28 may taper towards digitline DL (e.g., as shown).

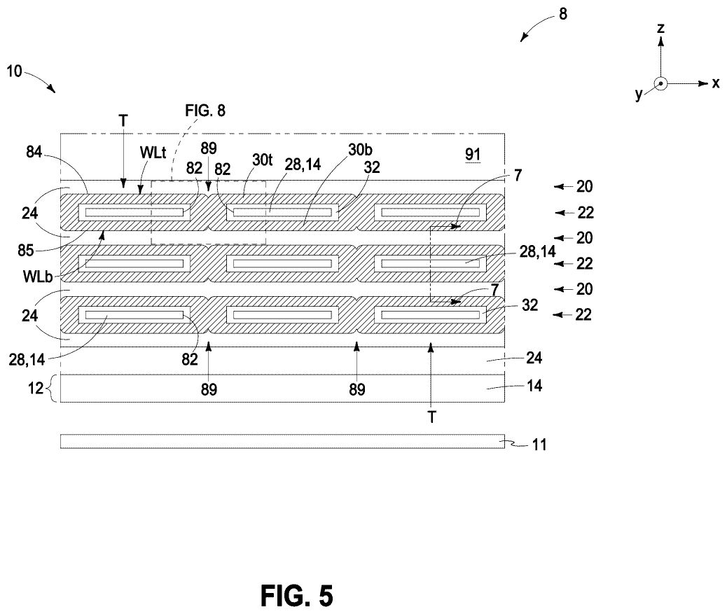

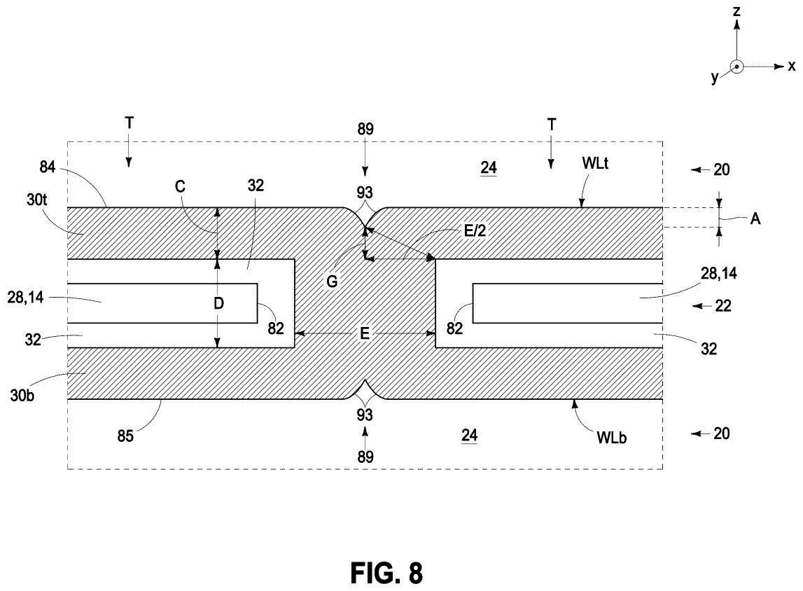

Example gate 30* (e.g., conductive metal material) of transistor T is gate-all-around channel region 28 having a gate insulator 32 (e.g., dielectric or ferroelectric) between at least channel region 28 and gate 30*. Gate 30* comprises part of a one of a plurality of horizontal conductive access lines WL* that individually directly electrically couple together multiple gates 30* of different ones of horizontal transistors T that are in the same memory-cell tier 22*. Access lines WL* are horizontally elongated in the x-direction and are spaced relative one another in the y-direction. An example insulator material 40 (e.g., silicon nitride) is laterally proximate lateral sides/edges of gates 30* (e.g., digitline-side edge 81 and capacitor-side edge 83). In one embodiment and as shown, gate 30* comprises a top gate 30t that is part of a top conductive access line WLt and comprises a bottom gate 30b that is part of a bottom conductive access line WLb. In one embodiment and as shown, gate insulator 32 extends laterally beyond digitline-side edge 81 (FIG. 7) and/or is along opposing z-direction sides 82 of channel material 14 (FIGS. 5 and 8). Sides 82 may be wholly or partially curved along the z-direction (not shown). Individual access lines WL* are horizontally between channel material 14 of immediately-x-direction-adjacent horizontal transistors T (e.g., gate-all-around). The y-direction lengths of conductive access lines WLt and WLb are diagrammatic. Such may be of equal or different lengths relative one another than is shown and/or may or may not be centered in the y-direction (with channel region 28) between the capacitors and transistors.

In some embodiments, top and bottom surfaces 84, 85, respectively, of individual access lines WL* have a depression 89 between channel material 14 of immediately-x-direction-adjacent horizontal transistors T (FIGS. 5 and 8). In one of such embodiments and as shown, individual depressions 89 are centered in the x-direction between immediately-x-direction-adjacent horizontal transistors T. Further, in one of such embodiments and as shown, individual depressions 89 have sidewalls 93 that are opposing in the x-direction and that are curved along the z-direction.

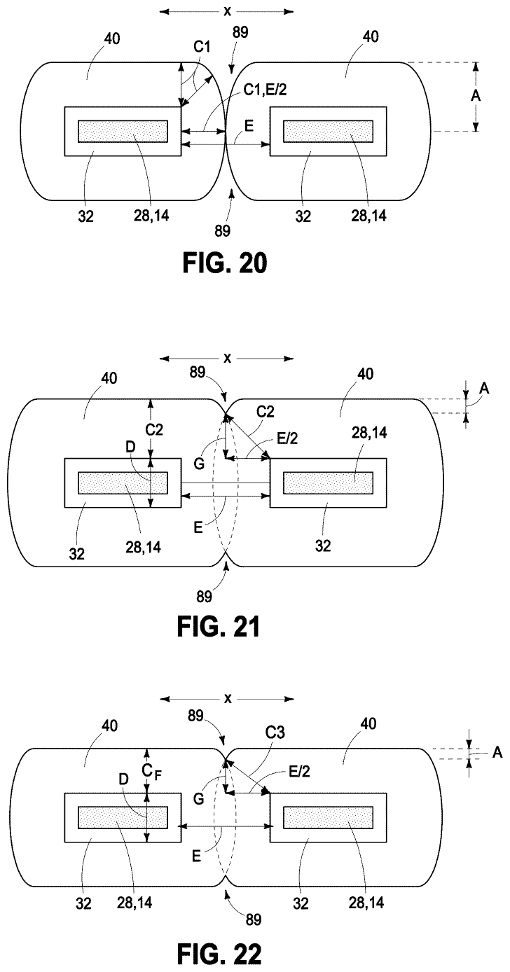

In some embodiments, and referring primarily to FIG. 8, (A) is less than (B), where:
(A): maximum vertical depth of individual of depressions 89; and
(B):

$$C + \frac{D}{2} - \sqrt{{C}^{2} - {( \frac{E}{2} )}^{2}}$$

where:
the “C” is maximum vertical thickness of top or bottom gate 30t, 30b directly above or directly below gate insulator 32 of individual of horizontal transistors T;
the “D”, in the individual horizontal transistors T, is maximum vertical thickness of channel material 14 plus maximum vertical thickness of gate insulator 32 that is directly above channel material 14 plus maximum vertical thickness of gate insulator 32 that is directly below channel material 14; and
the “E” is minimum horizontal distance between gate insulator 32 of immediately-x-direction-adjacent horizontal transistors T.
   In some embodiments, the (A) is at least 5% less than the (B), the (A) is at least 10% less than the (B), the (A) is no more than 75% less than the (B), and the (A) is no more than 50% less than the (B). Such may result in and from method embodiments described below (and from other methods) from modeling initially-formed sacrificial material 40 (referred to below and later with respect to FIGS. 20-22) on ends of immediately-x-direction-adjacent channel regions 28 as having elliptical arcs (e.g., sidewalls 93) having a distance to gate insulator 32 (C2 in FIG. 21), such distance initially being equal to maximum thickness of initially-formed sacrificial material 40 above gate insulator 32 (C2 in FIG. 21). Thereby, it can be modeled that maximum depression depth (A) equals C plus one-half of E, minus G, where:

$$G = \sqrt{{C}^{2} - {( \frac{E}{2} )}^{2}}$$

and thus (B) being:

$$C + \frac{D}{2} - \sqrt{{C}^{2} - {( \frac{E}{2} )}^{2}}$$

In method embodiments, (A) may be equal to (B) (at least initially in some method embodiments as described with reference to FIG. 20-22 below) for C being equal to or greater than one-half of E so bridging of sacrificial material 40 at least initially occurs across gap E. In some method embodiments (referred to below), reducing vertical thickness of an initially-formed thicker sacrificial material 40 to a reduced final thickness can desirably result in (A) being less than (B) with respect to the conductive material of access lines WL*. Such may be achieved by other methods.

Example capacitor C comprises a storage-node electrode 33, a common electrode 34 (e.g., comprising conductive metal material 70 and conductively-doped polysilicon 71) that is common (directly electrically coupled) to a plurality of capacitors C (at least some, not necessarily all) of memory cells MC, and a capacitor insulator 36 there-between (e.g., dielectric or ferroelectric). Storage-node electrode 33 is directly coupled to first source/drain region 23 of transistor T. Conductively-doped semiconductive material 99 (e.g., conductively-doped epitaxial silicon) may be between storage-node electrode 33 and first source/drain region 23 (e.g., and such may be considered as a part of either or both).

Digitlines DL (e.g., comprising conductive materials 13 and 15) extend through vertically-alternating tiers 20 and 22*. Conductively-doped semiconductive material 99 may be between/proximate digitline DL and second source/drain region 26. Digitlines DL of different immediately-horizontally-adjacent memory cells MC running into and out of the plane of the page upon which FIG. 3 lies (in the x-direction) may be isolated relative one another by insulative material 62 (e.g., silicon dioxide and/or silicon nitride). Individual second source/drain regions 26 of individual transistors T that are in different memory-cell tiers 22* are electrically coupled (e.g., directly electrically coupled) to individual digitlines DL. Capacitor C and horizontal transistor T may be considered as being horizontally spaced relative one another along horizontal axis 35 (FIG. 7) along the y-direction.

Any other attribute(s) or aspect(s) as shown and/or described herein with respect to other embodiments may be used in the embodiments shown and described with reference to the above embodiments.

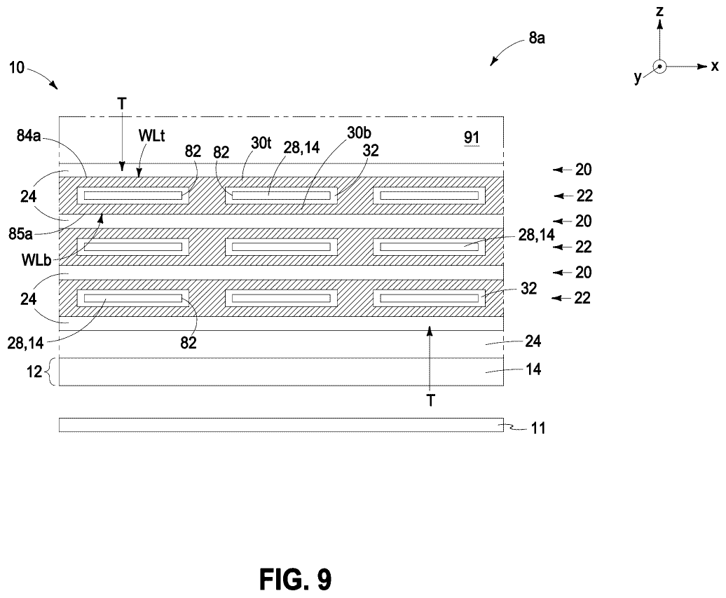

An alternate embodiment construction/memory circuitry 8a is shown in FIG. 9 (corresponding to FIG. 5 of the first-described embodiments). Like numerals from the above-described embodiments have been used where appropriate, with some construction differences being indicated with the suffix “a” or with different numerals. Memory circuitry 8a comprises vertically alternating insulative tiers (e.g., 20) and memory-cell tiers (e.g., 22*). Memory cells (e.g., MC as shown in FIG. 3, such view being the same with respect to construction/memory circuitry 8a and therefore not separately shown) are in the memory-cell tiers and that individually comprise a horizontal transistor (e.g., T) comprising a top gate (e.g., 30t) and a bottom gate (e.g., 30b) having channel material (e.g., 14) vertically there-between. The top and bottom gates comprise part of one of a plurality of access lines (e.g., WL*) that individually directly electrically couple together multiple of the gates of different ones of the horizontal transistors that are in the same memory-cell tier. Individual of the access lines are horizontally elongated in a horizontal x-direction. The individual access lines are horizontally between the channel material of the horizontal transistors that are immediately-adjacent one another in the x-direction. Top and bottom surfaces (e.g., 84a and 85b, respectively) of individual access lines WL* are everywhere horizontally planar between the immediately-x-direction-adjacent horizontal transistors (no depressions 89 in construction 8a as are in construction 8). Any other attribute(s) or aspect(s) as shown and/or described herein with respect to other embodiments may be used.

Embodiments of the invention encompass methods used in forming memory circuitry, by way of example only that incorporates device/structure as referred to above. Nevertheless, the method embodiments may incorporate, form, and/or have any of the attributes described with respect to device embodiments.

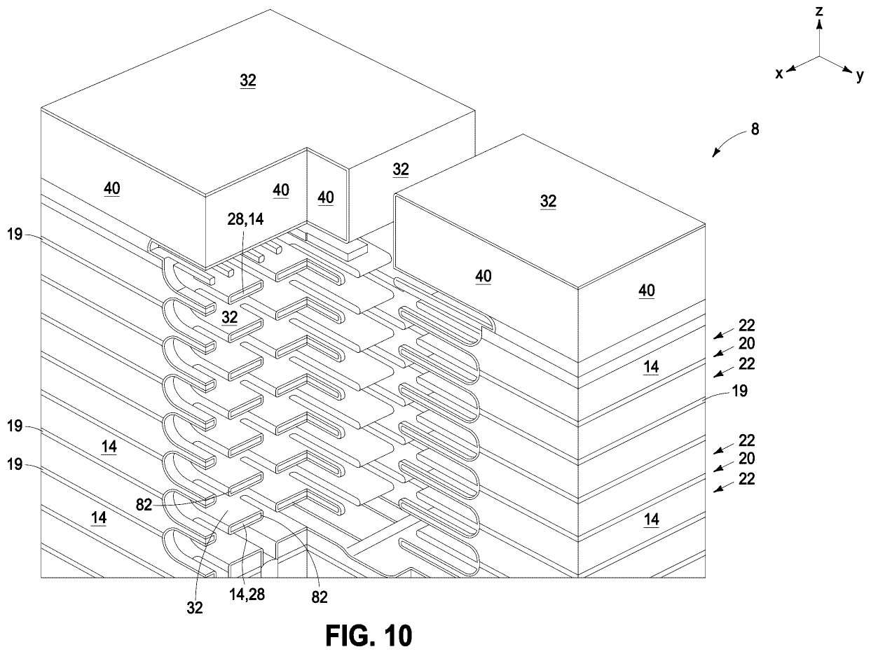

FIGS. 10-19 by way of example sequentially show predecessor constructions in an example method used in forming memory circuitry in accordance with embodiments of the invention. Such memory circuitry ultimately comprises vertically-stacked memory cells individually comprising a horizontal transistor and a capacitor electrically coupled (e.g., directly) therewith. Such memory circuitry may comprise structural embodiments of the invention as described above with respect to FIGS. 3-9.

Referring to FIG. 10, vertically-alternating insulative tiers 20 and memory-cell tiers 22* have been formed (e.g., comprising a silicon-germanium alloy 19 and semiconductor material 14, respectively). Memory cells (not-yet-formed) of memory-cell tiers 22* individually comprise a horizontal transistor (not-yet-completely-formed) and a capacitor (not-yet-formed) in a finished memory-circuitry construction. A plurality of channel regions 28 has been formed in memory-cell tiers 22* and that are spaced relative one another along a horizontal x-direction. Individual of the channel regions will comprise part of individual horizontal transistors T (not-yet-shown) being formed (in the finished-memory-circuitry construction). Gate insulator 32 has been formed about channel regions 28 and is accordingly in one embodiment along opposing z-direction sides 82 of channel material 14.

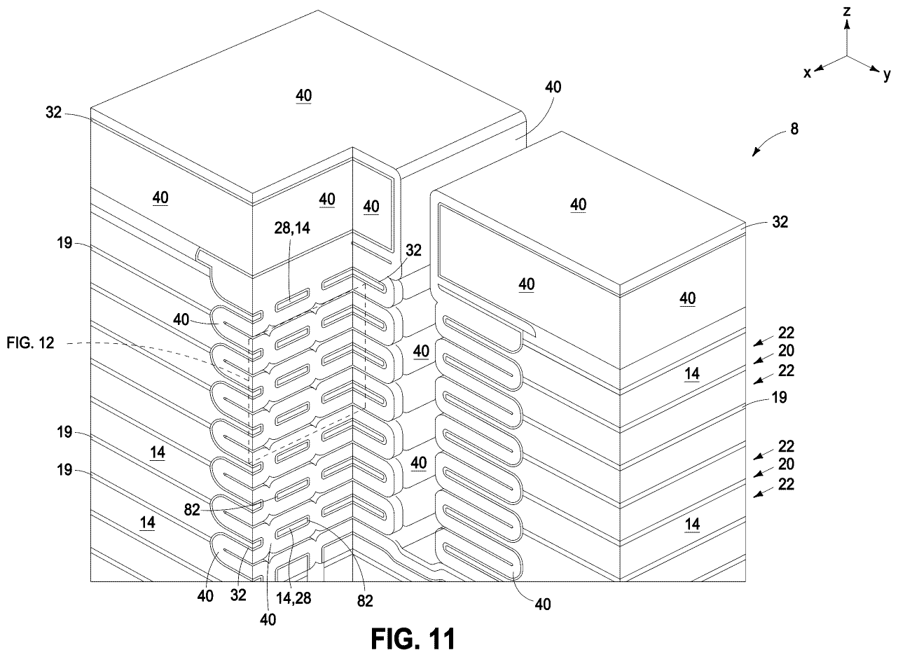

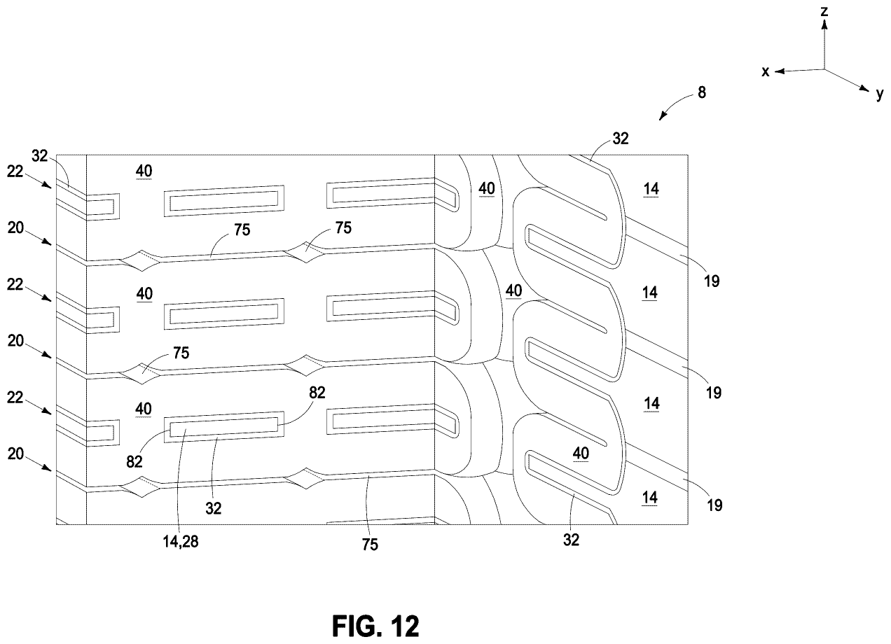

Referring to FIGS. 11 and 12, sacrificial material 40 (e.g., insulating material such as silicon nitride) has been formed directly above, directly below, and horizontally between immediately-x-direction-adjacent channel regions 28. Sacrificial material 40 has been formed to leave a void-space 75 in insulative tiers 20 vertically between immediately-vertically-adjacent memory cell tiers 22*. Void-space 75 is ideally continuous in the x and y directions and as thin as practical in the z-direction yet to still allow a subsequent etching fluid therein.

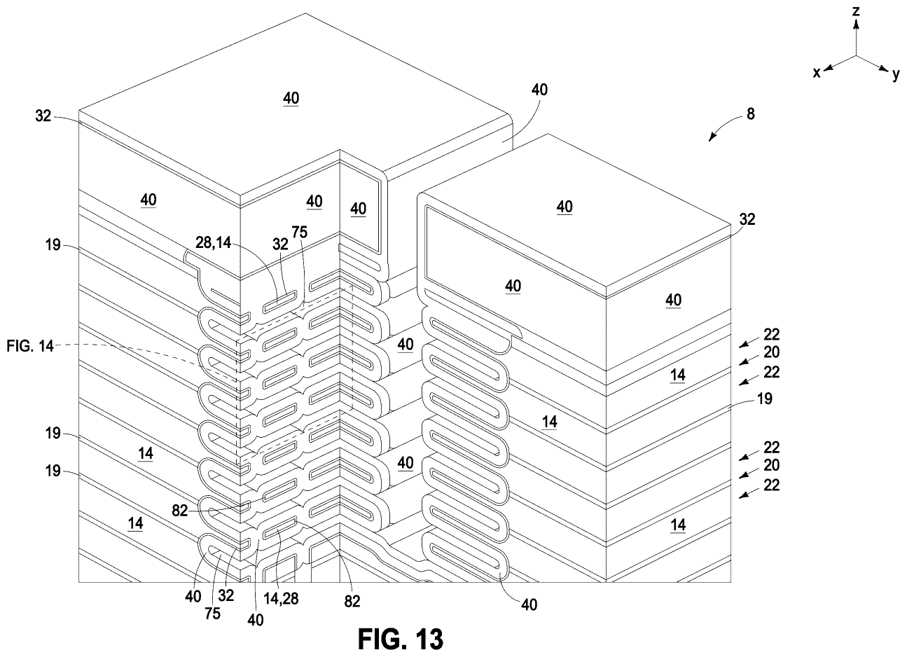

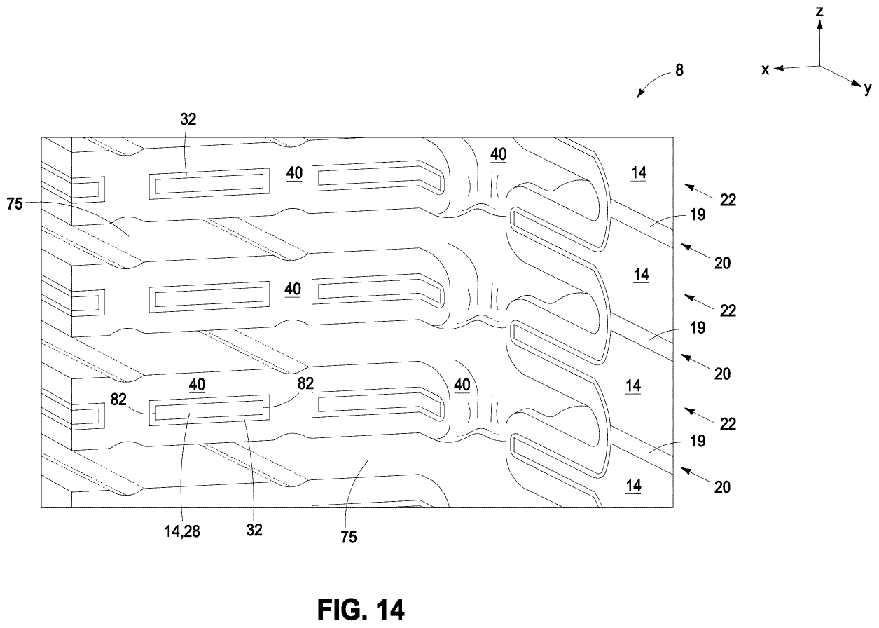

Referring to FIGS. 13 and 14, some and only some of sacrificial material 40 has been removed to vertically widen void-space 75 (e.g., by selective etching using H₃PO₄ when material 40 is silicon nitride).

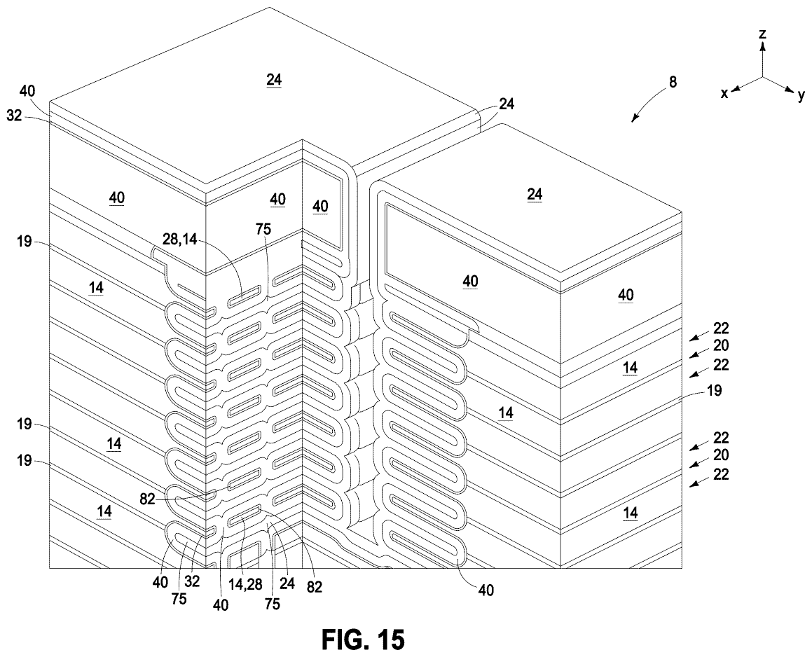

Referring to FIG. 15, insulative material 24 has been formed in widened-void-space 75.

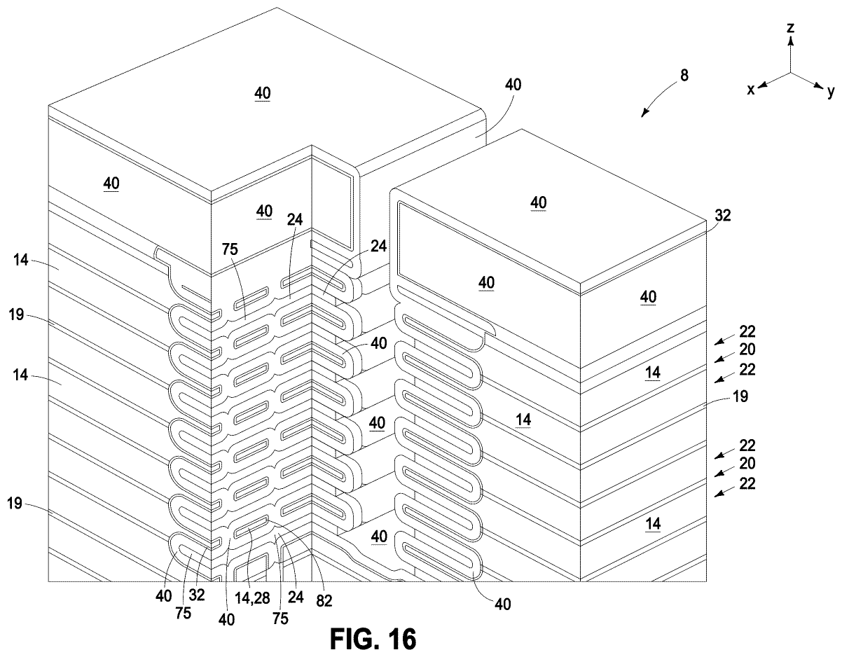

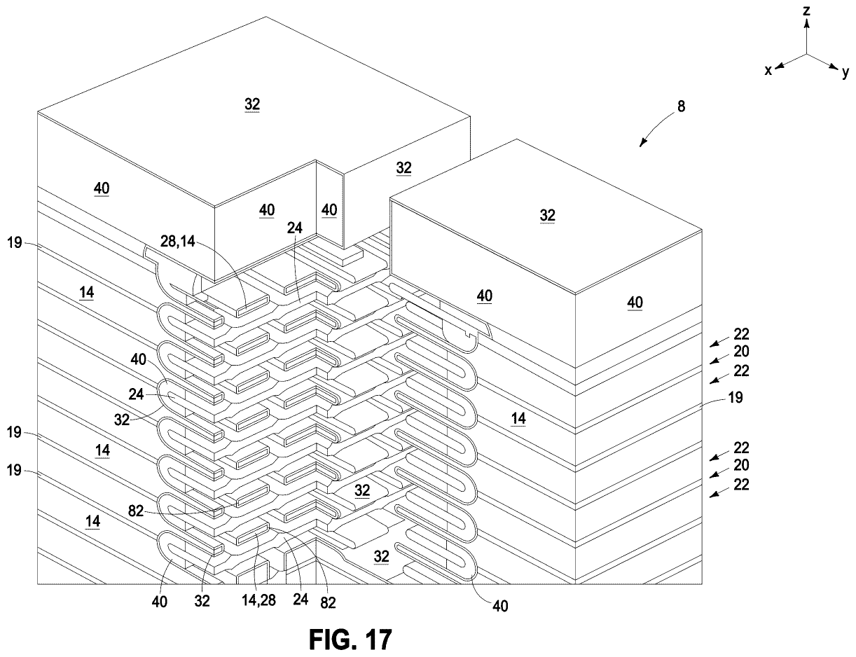

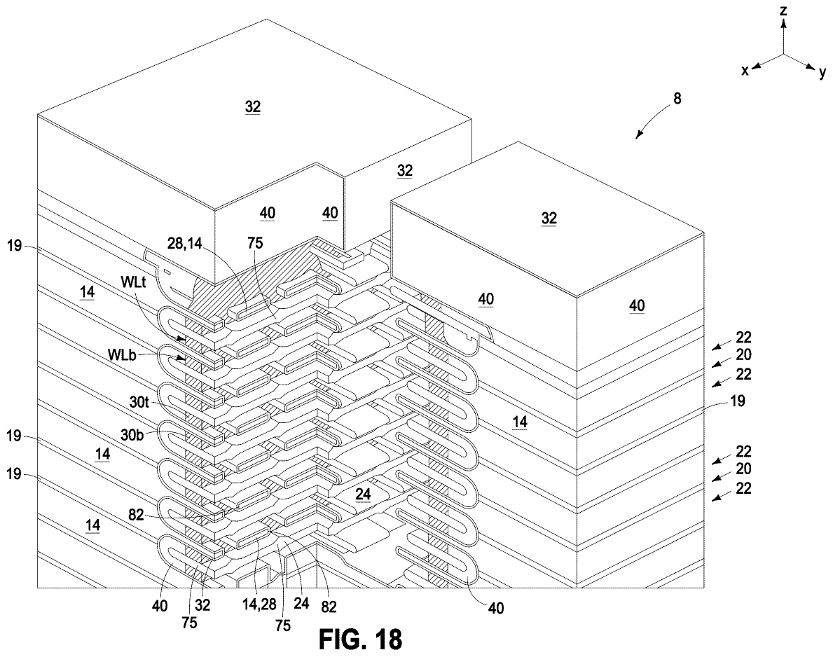

After forming insulative material 24, at least some of sacrificial material 40 is replaced with conductive material that comprises a gate of the individual horizontal transistors being formed. An example manner of doing so is described with reference to FIGS. 16-18. FIG. 16 shows recessing of insulative material 24 (e.g., by etching). FIG. 17 shows recessing of sacrificial material 40 (e.g., by etching). FIG. 18 shows back-filling of void-space left by the recessing of sacrificial material 40 with conductive material that comprises a gate 30* of the individual transistors being formed (and WL's*). In such example embodiment, only some of sacrificial material 40 was removed in FIG. 18 which results in only some of sacrificial material 40 being replaced by such conductive material.

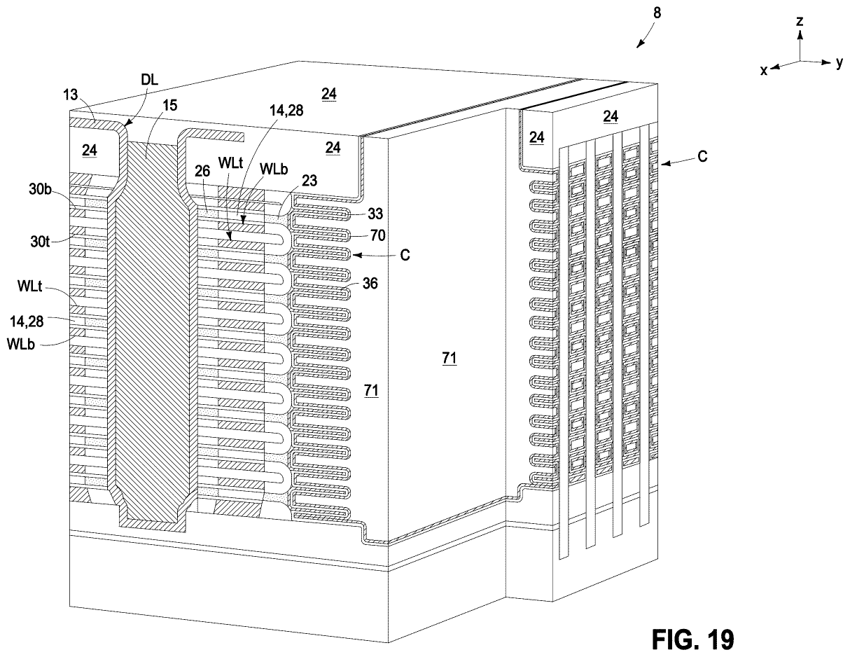

FIG. 19 shows further example processing resulting in digitlines DL and capacitors C, and construction 8 exemplified by FIGS. 1-8.

Processing as exemplified by FIGS. 10-19 may occur to result in depressions between immediately-x-direction-adjacent channel regions 28 (e.g., 89 as shown in FIGS. 5 and 8). Alternately, processing as described above, although starting out with depressions in sacrificial material 40, may remove all such depressions whereby top and bottom surfaces of the individual access lines formed are everywhere horizontally planar between immediately-x-direction-adjacent channel regions 28 (e.g., 84a and 84b, respectively as shown in FIG. 9). Regardless, any other attribute(s) or aspect(s) as shown and/or described herein with respect to other embodiments may be used.

Some embodiments of the invention were motivated towards reducing existence or volume of void-spaces in the conductive material of access lines WL* that can develop between gate insulator 32 of immediately-horizontally-adjacent horizontal transistors T in the x-direction. Such void-spaces in worst case can lead to one or more complete y-direction break(s) in the access lines and thereby inoperative circuitry. In prior method where sacrificial/insulator material 40 was initially formed to its final thickness (FIGS. 13 and 14), depressions 89 were deeper than shown in FIGS. 13 and 14 (i.e., (A) was larger than is there-shown), C had to be greater than or equal to one-half of E (to bridge the E gap), and (A) equaled (B) [(B) being the equation identified above]).

For example, consider diagrammatic FIG. 20, which shows C1 being equal to one-half of E such that immediately-x-direction-adjacent regions of sacrificial/insulator material 40 just touch, as would occur with such a so-achieved deposition of sacrificial/insulator material 40 (which is largely conformal, but not perfectly conformal [non-perfect conformality being shown], as would occur in typical chemical vapor deposition). Such results in the maximum possible vertical depth (A) of depressions 89 as shown (not desired) (if C1 were less than one-half of E [not shown], immediately-x-direction-adjacent regions of sacrificial/insulator material 40 would not touch [not shown]).

Now consider diagrammatic FIG. 21 which shows continued deposition of sacrificial/insulator material 40 to a greater thickness C2 whereby (A) reduces from what it was in FIG. 20 and (A) may [but not necessarily] equal (B) [(B) being the equation identified above]. However, in accordance with some method embodiments herein, (A) is further reduced by subsequent removal of sacrificial/insulator material 40 (e.g., by etching) to a final C_{F} as shown in diagrammatic FIG. 22 (C_{F} diagrammatically representing the C thickness of gate 30* in FIG. 8). Further, (A) may become less than [or more less than](B), and particularly where the larger C2 is/can be initially yet still providing sufficient vertical gap for the etching fluid to later get in and etch material 40. Alternately and/or additionally considered, final (A) may be the shortest/smallest the thicker the initial C1 is. Therefore or thereby, final (A) can be minimized or perhaps even eliminated [i.e., (A) goes to zero whereby there are no depressions 89, such as in FIG. 9) by starting with thick material 40 and later thinning it to its final thickness. Method embodiments may provide, although not require, the final vertical thickness C_{F} to be less than one-half of E and/or where (A) is less than (B) in the final construction (e.g., and a final C3 being greater than C_{F} as shown in FIG. 22). Such may facilitate reduction or elimination of void-spaces in the material of access lines WL* that is/will be between immediately-x-direction adjacent horizontal transistors. Additionally, and/or alternately, processing as described may facilitate, although not require, increase in comparative thickness of insulative tiers 20 relative to memory cell tiers 22* thereby improving isolation vertically and reducing parasitic capacitance.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The circuitry described herein (e.g., conductive vias thereof) may connect with circuitry that is on either the top or the bottom (i.e., either z-axis side) of the vertical stack regardless of orientation of the construction in three-dimensional space and which is not material to aspects of the inventions disclosed herein. For example, and by way of example only, conductive vias may connect with peripheral control circuitry that is beneath the stack with respect to the orientation shown in the drawings. As an alternate example, and by way of example only, conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, electronic components may be fabricated relative to the bottom of the stack with respect to the shown orientation but inverted therefrom during processing. Such electronic components may connect with conductive vias that extend through the stack to the substrate bonded with the other side that has such peripheral control circuitry. Regardless, constructions as shown and described herein may be processed, packaged, and/or mounted in any three-dimensional spatial orientation.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming memory circuitry comprises forming vertically-alternating insulative tiers and memory-cell tiers. Memory cells of the memory-cell tiers individually comprise a horizontal transistor in a finished-circuitry construction. A plurality of channel regions is formed in the memory-cell tiers and that are spaced relative one another along a horizontal x.direction. Individual of the channel regions comprise part of individual horizontal transistors in the finished-circuitry construction. Sacrificial material is formed directly above, directly below, and horizontally between immediately-x-direction-adjacent of the channel regions. The sacrificial material leaves void-space in the insulative tiers vertically between immediately-vertically-adjacent of the memory cell tiers. Some and only some of the sacrificial material is removed to vertically widen the void-space. Insulative material is formed in the widened-void-space. After forming the insulative material, at least some of the sacrificial material is replaced with conductive material that comprises a gate of the individual horizontal transistors.

In some embodiments, memory circuitry comprises insulative tiers and memory-cell tiers that vertically alternate relative one another in a vertical z-direction. Memory cells in the memory-cell tiers individually comprise a horizontal transistor that comprises a top gate and a bottom gate having gate insulator and channel material vertically there-between. The gate insulator is along opposing z-direction sides of the channel material. The top and bottom gates comprise part of one of a plurality of access lines that individually directly electrically couple together multiple of the gates of different ones of the horizontal transistors that are in the same memory-cell tier. Individual of the access lines are horizontally elongated in a horizontal x-direction. The individual access lines are horizontally between the channel material of immediately-x-direction-adjacent of the horizontal transistors. Top and bottom surfaces of the individual access lines have a depression between the channel material of the immediately-x-direction-adjacent horizontal transistors.
(A) is less than (B), where:
   (A): maximum vertical depth of individual of the depressions; and
   (B):

$$C + \frac{D}{2} - \sqrt{{C}^{2} - {( \frac{E}{2} )}^{2}}$$

where:
the “C” is maximum vertical thickness of the top or bottom gate directly above or directly below the gate insulator of individual of the horizontal transistors;
the “D”, in the individual horizontal transistors, is maximum vertical thickness of the channel material plus maximum vertical thickness of the gate insulator that is directly above the channel material plus maximum vertical thickness of the gate insulator that is directly below the channel material; and
the “E” is minimum horizontal distance between the gate insulator of the immediately-x-direction-adjacent horizontal transistors.

In some embodiments, memory circuitry comprises vertically alternating insulative tiers and memory-cell tiers. Memory cells in the memory-cell tiers individually comprise a horizontal transistor comprising a top gate and a bottom gate having channel material vertically there-between. The top and bottom gates comprise part of one of a plurality of access lines that individually directly electrically couple together multiple of the gates of different ones of the horizontal transistors that are in the same memory-cell tier. Individual of the access lines are horizontally elongated in a horizontal x-direction. The individual access lines are horizontally between the channel material of the horizontal transistors that are immediately-adjacent one another in the x-direction. Top and bottom surfaces of the individual access lines are everywhere horizontally planar between the immediately-x-direction-adjacent horizontal transistors.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming vertically-alternating insulative tiers and memory-cell tiers, memory cells of the memory-cell tiers individually comprising a horizontal transistor in a finished-circuitry construction;
forming a plurality of channel regions in the memory-cell tiers that are spaced relative one another along a horizontal x-direction, individual of the channel regions comprising part of individual of the horizontal transistors in the finished-circuitry construction;
forming sacrificial material directly above, directly below, and horizontally between immediately-x-direction-adjacent of the channel regions; the sacrificial material leaving void-space in the insulative tiers vertically between immediately-vertically-adjacent of the memory cell tiers;
removing some and only some of the sacrificial material to vertically widen the void-space;
forming insulative material in the widened-void-space; and
after forming the insulative material, replacing at least some of the sacrificial material with conductive material that comprises a gate of the individual horizontal transistors.

2. The method of claim 1 wherein the sacrificial material is insulating.

3. The method of claim 1 wherein the replacing is of only some of the sacrificial material.

4. The method of claim 2 wherein the sacrificial material is insulating.

5. The method of claim 1 wherein,
the insulative tiers and the memory-cell tiers vertically alternate relative one another in a vertical z-direction;
the gate comprises a top gate and a bottom gate having gate insulator and channel material of the channel region vertically there-between, the gate insulator being along opposing z-direction sides of the channel material;
the top and bottom gates comprising the conductive material which is part of one of a plurality of access lines that individually directly electrically couple together multiple of the gates of different ones of the horizontal transistors that are in the same memory-cell tier, individual of the access lines being horizontally elongated in the horizontal x-direction, the individual access lines being horizontally between the immediately-x-direction-adjacent channel regions, top and bottom surfaces of the individual access lines having a depression between the immediately-x-direction-adjacent channel regions; and
(A) being less than (B), where:
(A): maximum vertical depth of individual of the depressions; and
(B):
$$C + \frac{D}{2} - \sqrt{{C}^{2} - {( \frac{E}{2} )}^{2}}$$
where:
the “C” is maximum vertical thickness of the top or bottom gate directly above or directly below the gate insulator of individual of the horizontal transistors;
the “D”, in the individual horizontal transistors, is maximum vertical thickness of the channel material plus maximum vertical thickness of the gate insulator that is directly above the channel material plus maximum vertical thickness of the gate insulator that is directly below the channel material; and
the “E” is minimum horizontal distance between the gate insulator of immediately-x-direction-adjacent of the horizontal transistors.

6. The method of claim 5 wherein the (A) is from 5% to 75% less than the (B).

7. The method of claim 6 wherein the (A) is from 10% to 75% less than the (B).

8. The method of claim 7 wherein the (A) is from 10% to 50% less than the (B).

9. The method of claim 1 wherein,
the gate comprises a top gate and a bottom gate having gate insulator and channel material of the channel region vertically there-between; and
the top and bottom gates comprising the conductive material which is part of one of a plurality of access lines that individually directly electrically couple together multiple of the gates of different ones of the horizontal transistors that are in the same memory-cell tier, individual of the access lines being horizontally elongated in the horizontal x-direction, the individual access lines being horizontally between the immediately-x-direction-adjacent channel regions, top and bottom surfaces of the individual access lines being everywhere horizontally planar between the immediately-x-direction-adjacent channel regions.

10. The method of claim 9 wherein the insulative tiers and the memory-cell tiers vertically alternate in a vertical z-direction, the horizontal transistor having gate insulator that is along opposing z-direction sides of the channel region.

11. Memory circuitry comprising:
insulative tiers and memory-cell tiers that vertically alternate relative one another in a vertical z-direction;
memory cells in the memory-cell tiers that individually comprise a horizontal transistor comprising a top gate and a bottom gate having gate insulator and channel material vertically there-between, the gate insulator being along opposing z-direction sides of the channel material;
the top and bottom gates comprising part of one of a plurality of access lines that individually directly electrically couple together multiple of the gates of different ones of the horizontal transistors that are in the same memory-cell tier, individual of the access lines being horizontally elongated in a horizontal x-direction, the individual access lines being horizontally between the channel material of immediately-x-direction-adjacent of the horizontal transistors, top and bottom surfaces of the individual access lines having a depression between the channel material of the immediately-x-direction-adjacent horizontal transistors; and
(A) being less than (B), where:
(A): maximum vertical depth of individual of the depressions; and
(B):
$$C + \frac{D}{2} - \sqrt{{C}^{2} - {( \frac{E}{2} )}^{2}}$$
where:
the “C” is maximum vertical thickness of the top or bottom gate directly above or directly below the gate insulator of individual of the horizontal transistors;
the “D”, in the individual horizontal transistors, is maximum vertical thickness of the channel material plus maximum vertical thickness of the gate insulator that is directly above the channel material plus maximum vertical thickness of the gate insulator that is directly below the channel material; and
the “E” is minimum horizontal distance between the gate insulator of the immediately-x-direction-adjacent horizontal transistors.

12. The memory circuitry of claim 11 wherein the (A) is at least 5% less than the (B).

13. The memory circuitry of claim 12 wherein the (A) is at least 10% less than the (B).

14. The memory circuitry of claim 11 wherein the (A) is no more than 75% less than the (B).

15. The memory circuitry of claim 14 wherein the (A) is from 5% to 75% less than the (B).

16. The memory circuitry of claim 15 wherein the (A) is from 10% to 75% less than the (B).

17. The memory circuitry of claim 16 wherein the (A) is from 10% to 50% less than the (B).

18. The memory circuitry of claim 11 wherein individual of the depressions are centered in the x-direction between the immediately-x-direction-adjacent horizontal transistors.

19. The memory circuitry of claim 11 wherein individual of the depressions have sidewalls opposing in the x-direction that are curved along the z-direction.

20. The memory circuitry of claim 11 wherein,
the (A) is from 5% to 75% less than (B);
individual of the depressions are centered in the x-direction between the immediately-x-direction-adjacent horizontal transistors; and
the individual depressions have sidewalls opposing in the x-direction that are curved along the z-direction.

21. Memory circuitry comprising:
vertically alternating insulative tiers and memory-cell tiers;
memory cells in the memory-cell tiers that individually comprise a horizontal transistor comprising a top gate and a bottom gate having channel material vertically there-between; and
the top and bottom gates comprising part of one of a plurality of access lines that individually directly electrically couple together multiple of the gates of different ones of the horizontal transistors that are in the same memory-cell tier, individual of the access lines being horizontally elongated in a horizontal x-direction, the individual access lines being horizontally between the channel material of the horizontal transistors that are immediately-adjacent one another in the x-direction, top and bottom surfaces of the individual access lines being everywhere horizontally planar between the immediately-x-direction-adjacent horizontal transistors.

22. The memory circuitry of claim 21 wherein the insulative tiers and the memory-cell tiers vertically alternate in a vertical z-direction, the horizontal transistor having gate insulator that is along opposing z-direction sides of the channel material.
